(19) United States
(12) Patent Application Publication
(10) Pub. No.: US 2002/0192926 A1
(43) Pub. Date: Dec. 19, 2002

(54) High contrast lithography alignment marks for semiconductor manufacturing

(76) Inventors: Uwe Paul Schroeder, Dresden (DE); Tobias Mono, Dresden (DE)

Correspondence Address: Infineon Technologies North America Corp., c/o Siemens Corporation, Intellectual Property Department, 186 Wood Avenue South, Iselin, NJ, 08830, US

(21) Appl. No.: 09/883,437

(22) Filed: Jun. 18, 2001

(51) Int. Cl. H01L 21/00; H01L 21/76

(52) U.S. Cl. 438/401

(57) ABSTRACT

A method for providing contrast for alignment marks after a blanket metal deposition is disclosed. A trench is provided in a first region and a trench is provided in an alignment mark region of a semiconductor wafer. A first metal is deposited on the wafer, and the first metal is blocked from filling the trench in the alignment mark region to maintain the trench in the alignment mark region in an unfilled state. The wafer is planarized to remove the first metal from a top surface. A blanket depositing of a second metal layer is performed on the first region and the alignment mark region such that the trench in the alignment mark region is suitable for use as a scattering alignment mark.

### BACKGROUND

1. Technical Field

This disclosure relates to semiconductor fabrication, and more particularly, to methods and devices for providing high contrast alignment marks for laserlight scattering alignment (LSA) systems.

2. Description of the Related Art

Alignment marks are employed in semiconductor fabrication to provide alignment between process steps. Typical alignment marks include a trench or plateau formed on a first layer which is employed to align a mask of other processing tool to provide alignment between layers formed on a semiconductor wafer.

Current alignment marks produced with a damascene integration scheme, or more specifically an integration scheme requiring a metal layer to be polished down, generally suffer from poor contrast when using the laserlight scattering alignment (LSA) systems. These systems may include, for example, SVG MICRASCAN, available commercially from ASM Lithography, NIKON LSA, models S103, S203, S204, etc., available commercially from NIKON. These types of alignment systems rely on topography differences, or less desirable, reflectance differences between an interface alignment mark structure and its surrounding area.

Referring to FIG. 1, laserlight 10 is directed at a surface of a semiconductor structure 12. Structure 12 includes alignment marks 14. Alignment marks 14 may include trenches 16, plateaus 18 or both. Laserlight 10 is incident on the surface of structure 12 and is scattered. Scattered light 20 is measured as the laserlight 10 is scanned across the surface. Topography differences or reflectance differences are measured as a function of position to determine the interfaces between alignment marks 14 and the surrounding area.

Referring to FIG. 2, a damascene integration method includes etched trenches 16, which are filled with metal 22 and then polished flat. Subsequently, a blanket metal layer 24 is deposited, which provides very little topography (or reflectance differences) because of the previously polished layer 22. The small remaining topography is generally not enough to allow LSA alignment since laserlight 10 is no longer scattered. Moreover, the alignment signal quality varies from wafer to wafer and lot to lot, thus resulting in large differences within a lot and lot to lot overlay variability. This reduces the overlay confidence and impacts yield.

In this case, optical alignment methods cannot be employed, because even a very thin metal layer absorbs all the reflected light from the previous layers.

Therefore, a need exists for providing contrast of alignment marks to permit laserlight scattering alignment. A further need exists for permitting laserlight scattering alignment metal damascene steps with subsequent blanket metal deposition steps.

### SUMMARY OF THE INVENTION

A method for providing contrast for alignment marks after a blanket metal deposition is disclosed. A trench is provided in a first region and a trench is provided in an alignment mark region of a semiconductor wafer. A first metal is deposited on the wafer, and the first metal is blocked from filling the trench in the alignment mark region to maintain the trench in the alignment mark region in an unfilled state. The wafer is planarized to remove the first metal from a top surface. A blanket depositing of a second metal layer is performed on the first region and the alignment mark region such that the trench in the alignment mark region is suitable for use as a scattering alignment mark.

These and other objects, features and advantages of the present invention will become apparent from the following detailed description of illustrative embodiments thereof, which is to be read in connection with the accompanying drawings.

### BRIEF DESCRIPTION OF DRAWINGS

This disclosure will present in detail the following description of preferred embodiments with reference to the following figures wherein:

FIG. 1 is a schematic diagram showing a laserlight scattering alignment system in accordance with the prior art;

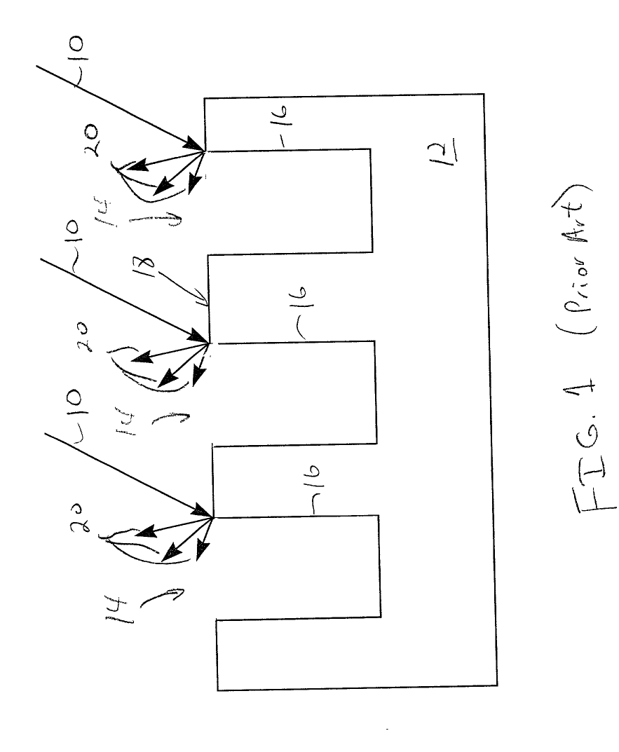

FIG. 2 is a schematic diagram showing a laserlight scattering alignment system after a blanket deposition of a metal in accordance with the prior art;

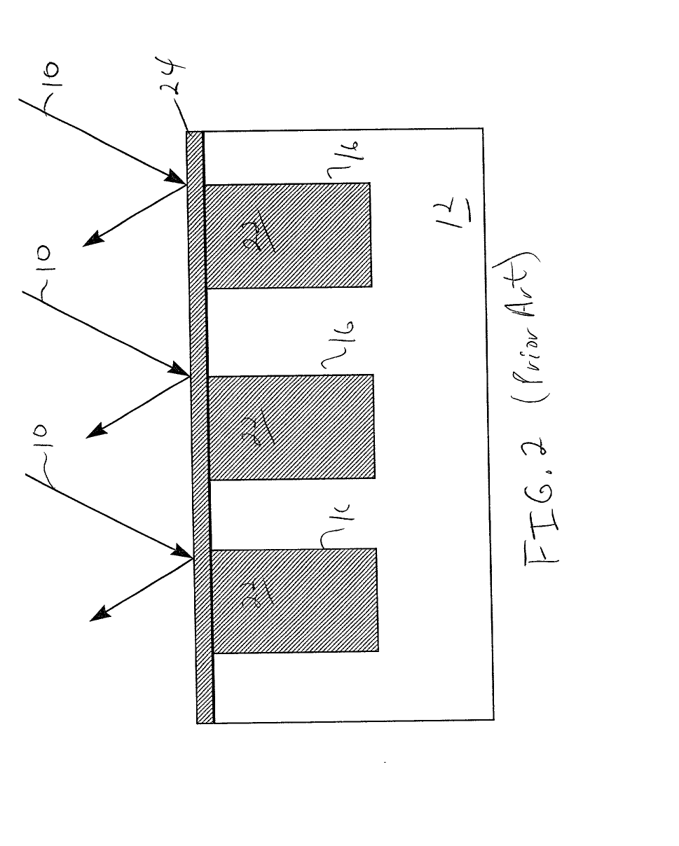

FIG. 3 is a partial cross-sectional view of a two regions of a semiconductor wafer showing trenches formed in a layer or substrate of the wafer in accordance with the present invention;

FIG. 4 is a partial cross-sectional view of the two regions of FIG. 3 showing a seed layer removed from an alignment mark trench in accordance with the present invention;

FIG. 5 is a partial cross-sectional view of the two regions of FIG. 4 after resist is removed in accordance with the present invention;

FIG. 6 is a partial cross-sectional view of the two regions of FIG. 5 showing a metal layer deposited without filling the trench in the alignment mark region in accordance with the present invention;

FIG. 7 is a partial cross-sectional view of the two regions of FIG. 6 showing the seed layer and the metal layer planarized in accordance with the present invention;

FIG. 8 is a partial cross-sectional view of the two regions of FIG. 7 showing a blanket metal deposition in accordance with the present invention;

FIG. 9 is a partial cross-sectional view of the two regions of FIG. 8 showing a scanning laser employed in detecting the topography of an alignment mark after a blanket deposition in accordance with the present invention;

FIG. 10 is a partial cross-sectional view of the two regions of FIG. 3 showing a blocking material deposited for another embodiment in accordance with the present invention;

FIG. 11 is a partial cross-sectional view of the two regions of FIG. 10 showing the blocking material patterned to fill an alignment mark in accordance with the present invention;

FIG. 12 is a partial cross-sectional view of the two regions of FIG. 11 showing an optional seed layer formed on the blocking material in accordance with the present invention;

FIG. 13 is a partial cross-sectional view of the two regions of FIG. 12 showing a metal layer deposited in accordance with the present invention;

FIG. 14 is a partial cross-sectional view of the two regions of FIG. 13 showing the metal layer and the blocking material planarized in accordance with the present invention;

FIG. 15 is a partial cross-sectional view of the two regions of FIG. 14 showing the blocking material removed from the alignment mark in accordance with the present invention; and

FIG. 16 is a partial cross-sectional view of the two regions of FIG. 15 showing a blanket metal deposition in accordance with the present invention.

### DETAILED DESCRIPTION OF PREFERRED EMBODIMENTS

The present invention provides alignment mark structures, which avoid metal deposition on the alignment marks. This may be performed in a plurality of ways. In one embodiment, a blocking layer is formed in the alignment mark region during metal deposition steps. In another embodiment, a seed layer for forming the metal is blocked so that metal growth is not initiated from surfaces of the alignment marks. Other embodiment, may remove the seed layer after deposition to prevent metal growth. These and other methods will be described in detail with reference to the drawings.

For simplicity, the FIGS. show two regions of a semiconductor memory chip 100. These two regions include, in this example, a memory array region 102 and an alignment mark region 104. These regions may be located at any position on a semiconductor wafer and are schematically depicted to demonstrate one implementation of the present invention. Memory array region 102 is shown for illustrative purposes only, other regions may also be employed. Chip 100 may include memory devices, application specific chips or any other semiconductor device.

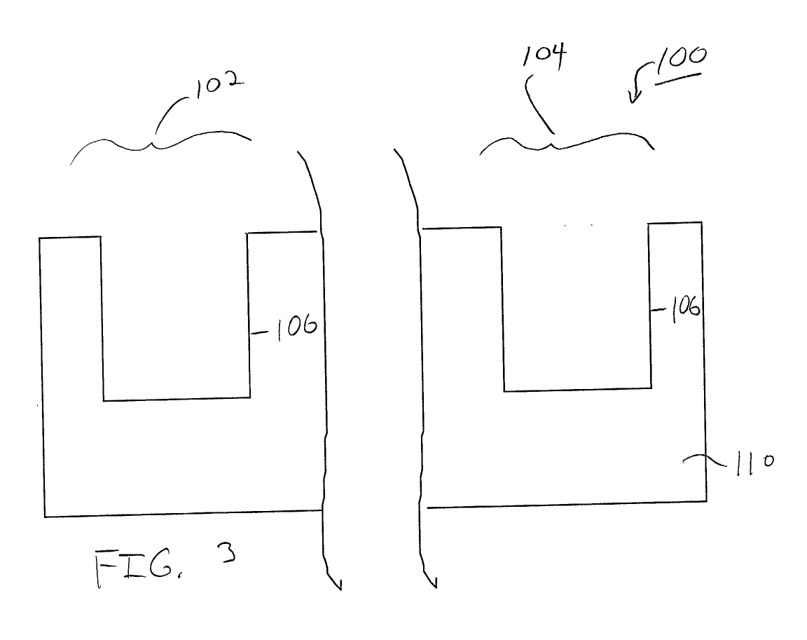

Referring now in specific detail to the drawings in which like reference numerals identify similar or identical elements throughout the several views, and initially to FIG. 3, a cross-sectional view of a semiconductor wafer 100 is illustratively shown. As described above, wafer 100 includes memory array region 102, which is illustrative of a memory array device to be fabricated on semiconductor wafer 100. Other semiconductor devices are also contemplated in accordance with the present invention. Alignment mark region 104 may be provided at any suitable position on wafer 100. Alignment mark region 104 illustratively may include trenches 106, plateaus and/or any other topographical features as an alignment mark or marks.

In the illustrative embodiment shown, a substrate 110 is patterned by known lithography and etching processes. Substrate 110 may include a semiconductor substrate, such as monocrystalline silicon, a dielectric layer or layers or any other layer which is to be aligned with a subsequent semiconductor device layer or mask. Trenches 106 are preferably formed simultaneously in regions 102 and 104.

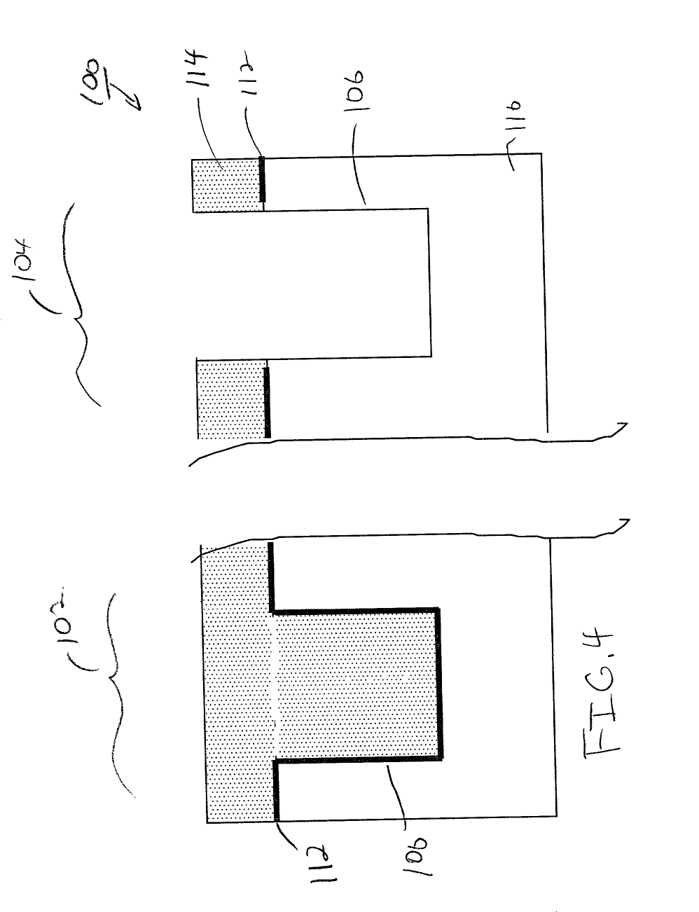

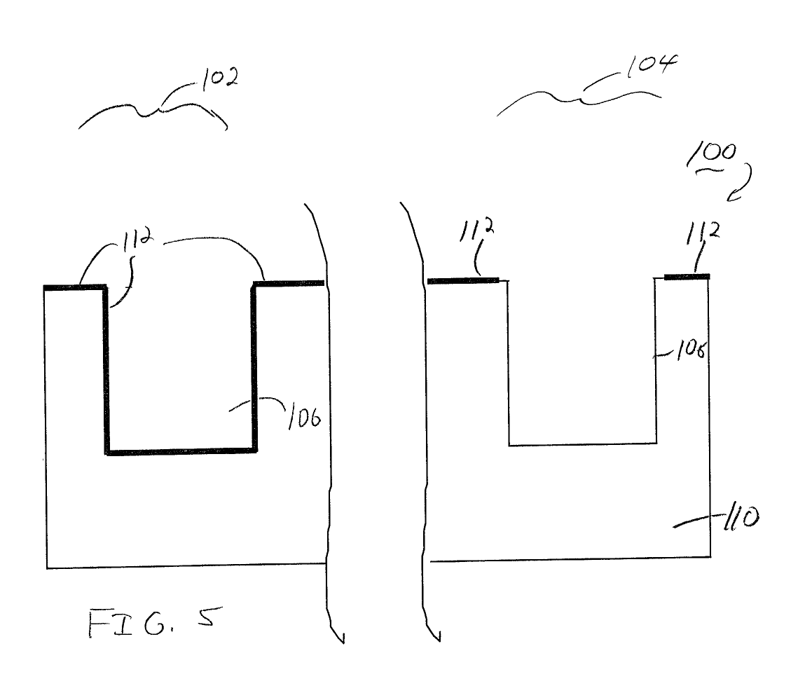

Referring to FIG. 4, in one embodiment, a metal layer to be deposited needs a seed layer to initiate deposition. For example, the seed layer may include copper or other suitable metals for metal layer deposition. A seed layer 112 may be formed over the surface of wafer 100. Seed layer 112 is removed from trench 106 in region 104 by patterning a resist layer 114 over trench 106 in regions 102 and 104 and etching away seed layer 112 in trench 106 by a wet or dry etching process. Resist 114 is then removed, as shown in FIG. 5.

In an alternate embodiment, seed layer 112 is prevented from forming in trench 106 of region 104 by providing a blocking material or layer in the trench during seed layer formation. This provides the same structure as shown in FIG. 5.

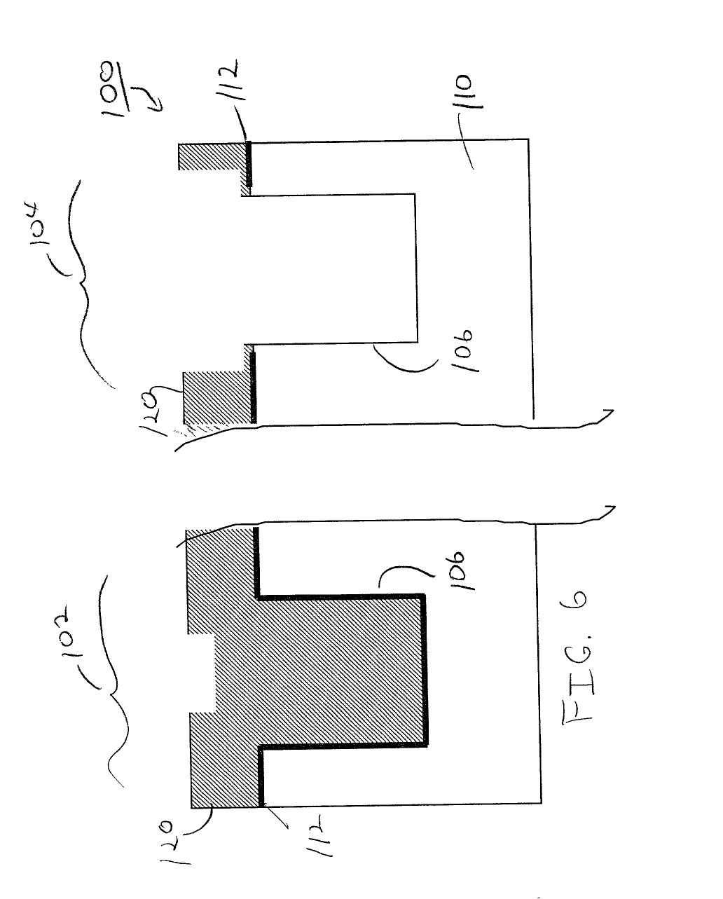

Referring to FIG. 6, a metal layer 120 is deposited on wafer 100. In this example, metal layer 120 includes copper or other metals which usually need a seed layer to initiate deposition. Since seed layer 112 has been removed from trench 106 in region 104, metal layer 120 does not from in trench 106 in region 104, but forms in areas including seed layer 112.

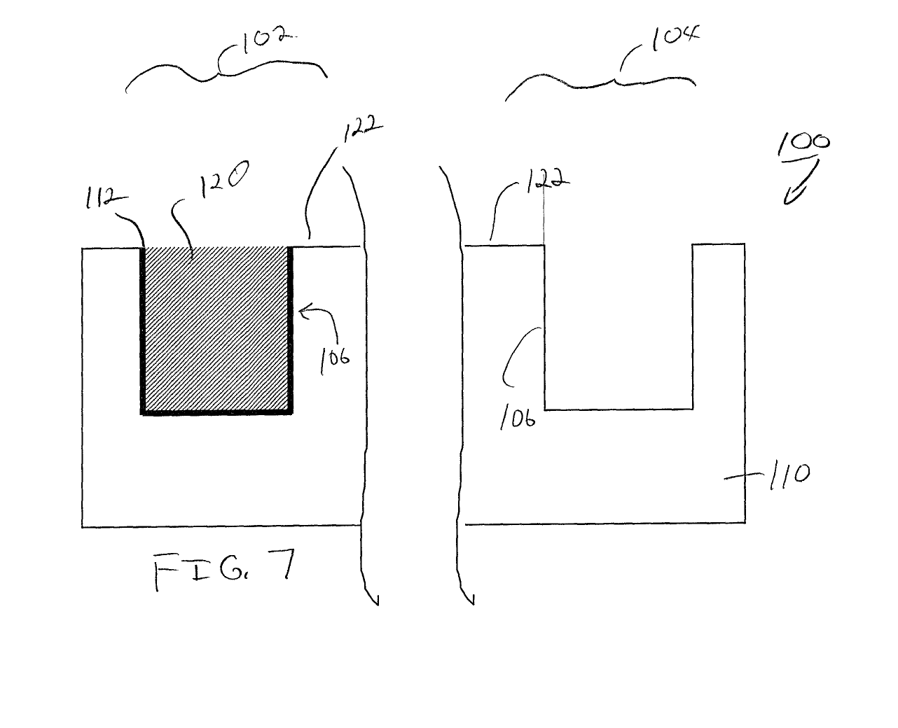

Referring to FIG. 7, metal layer 120 is planarized, preferably by a chemical-mechanical polishing (CMP) process. This removes metal layer 120 and seed layer 112 from a top surface 122 in regions including regions 102 and 104.

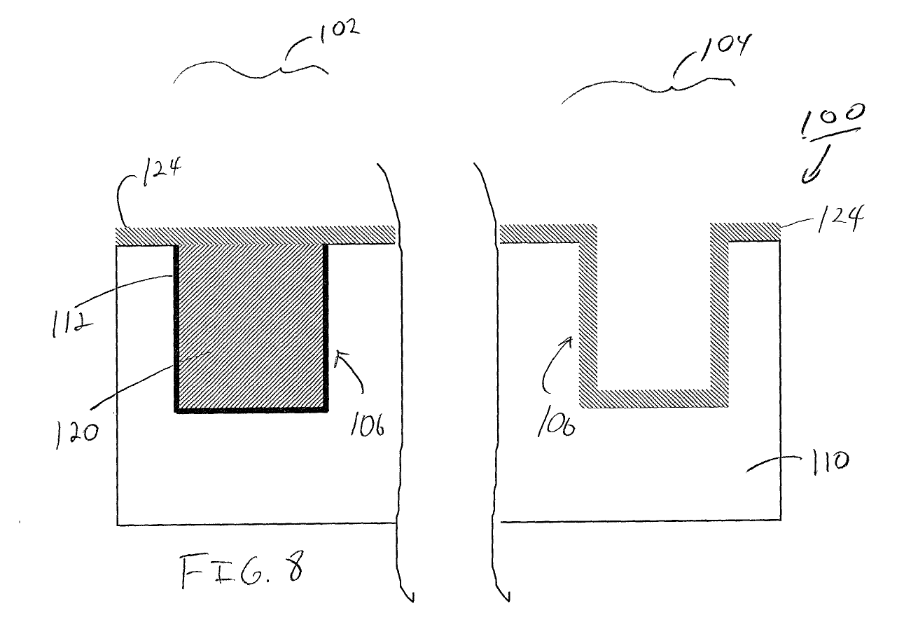

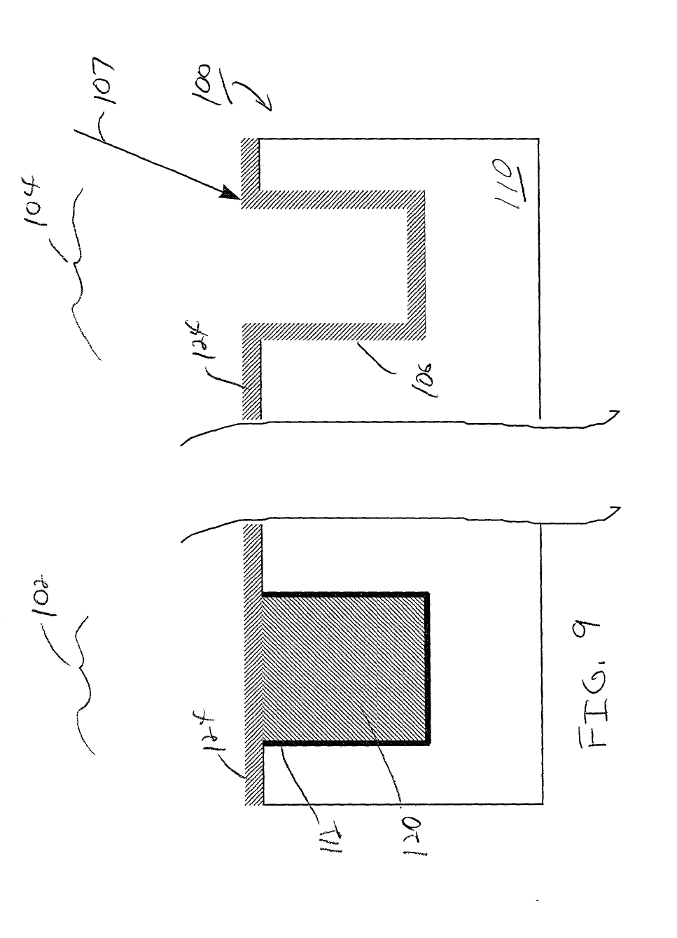

Referring to FIG. 8, a blanket metal 124 may be deposited over wafer 100. The blanket metal deposition is thin enough not to fill trench 106 in region 104. Advantageously, since trench 106 in region 104 is not filled with metal, trench 106 in region 104 provides an alignment mark suitable for scattering alignment systems, such as for example, laserlight scattering alignment (LSA) systems. As shown in FIG. 9 laserlight 107 is directed at wafer 100 and scanned across to determine the position of trench 106 in region 104.

Trench 106 in region 104 maintains its topographical features to provide distinct interfaces against which a photomask or subsequently processed layers can be aligned. Blanket metal 124, which may include, for example, copper tungsten, titanium, aluminum, etc., is patterned using a conventional lithography process in which a photomask (not shown) is aligned to alignment mark (trench 106 in region 104) to provide alignment between the underlying metal layer 120 and the pattern to be formed in blanket metal 124.

It is to be understood that the formation of metal layer 120 may be initiated in trench 106 in region 104 without seed layer 112. However, this layer would form at a much slower rate and the interfaces (trench walls) of trench will still be adequate for scattering alignment in accordance with the present invention.

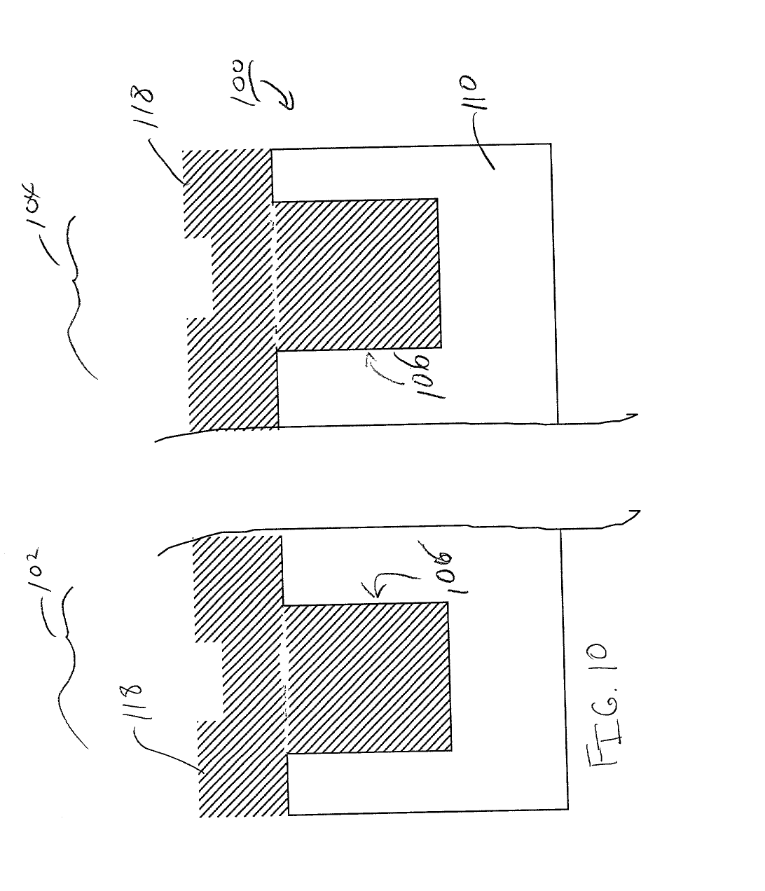

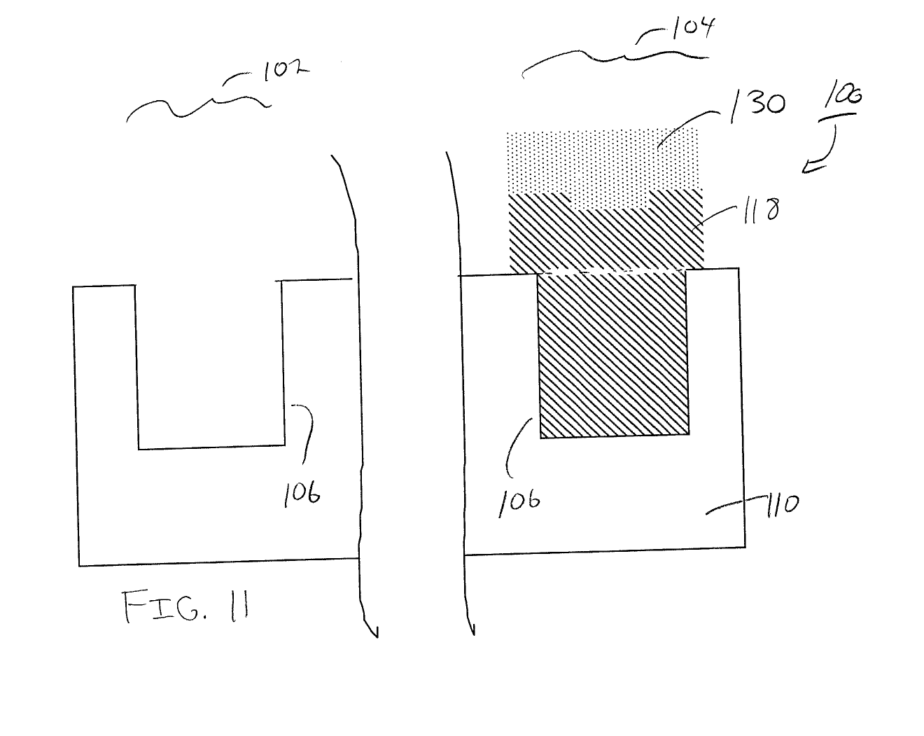

Referring to FIG. 10, in an alternate embodiment, beginning with the structure in FIG. 3, a block material 118 may be formed in region 104 to fill trench 106 in region 104. Block material 118 may be formed by depositing block material 118 over wafer 100, and patterning block material 118 by forming a photoresist 130 over block material 118 except in region 104, as shown in FIG. 11. Photoresist 130 is exposed and developed. Resist 130 is removed from region 102 and areas other than over trench 106 in region 104. Block material 118 may include, for example, silicon nitride or a photomask used for blocking and/or uncovering an alignment mark. Photoresist 130 may include, for example, a mid ultraviolet (MUV) resist. Advantageously, the blocking material can be patterned by employing, for example, mid ultraviolet (MUV) lithography, which does not have high requirements in terms of overlay and critical dimension (CD) control.

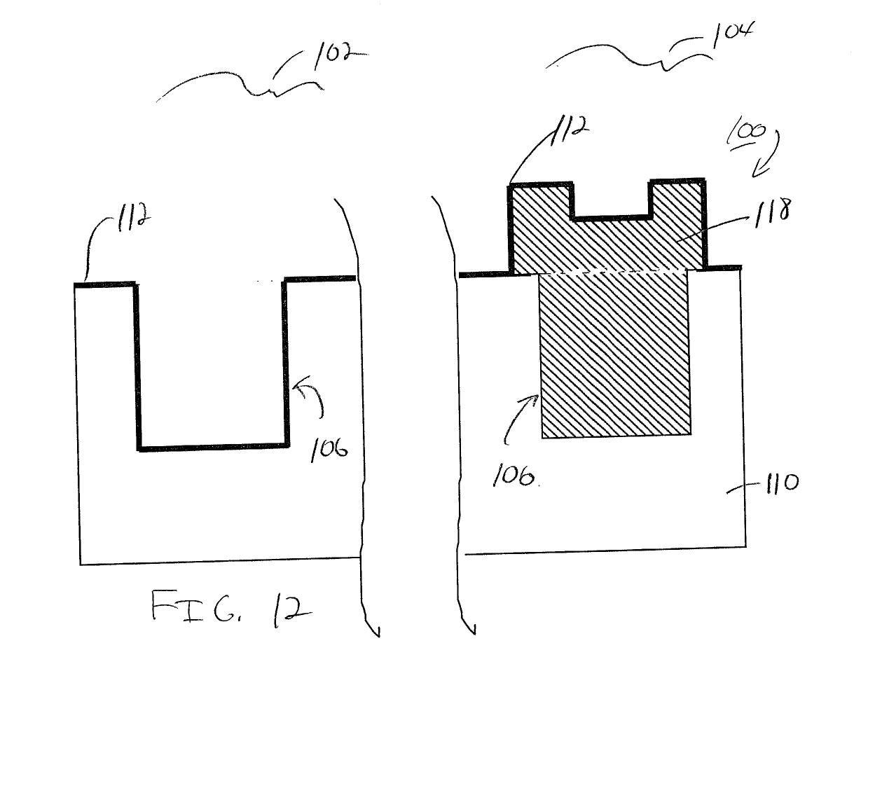

Referring to FIG. 12, block material 118 is removed from region 102 and photoresist 130 is removed from region 104. Now, block material 118 remains in trench 106 in region 104 to prevent the formation of metal therein in subsequent steps.

A seed layer 112 and a metal layer 122 are deposited over wafer 100. Seed layer 112 is optional as some metals which do not need a seed layer may be employed. Seed layer 122 may include, for example, tantalum or tantalum nitride, if a copper metal deposition will be employed. A CMP process may be performed to remove access block material 118 (material 118 outside of trench 106 in region 104) prior to forming seed layer 112 or metal deposition.

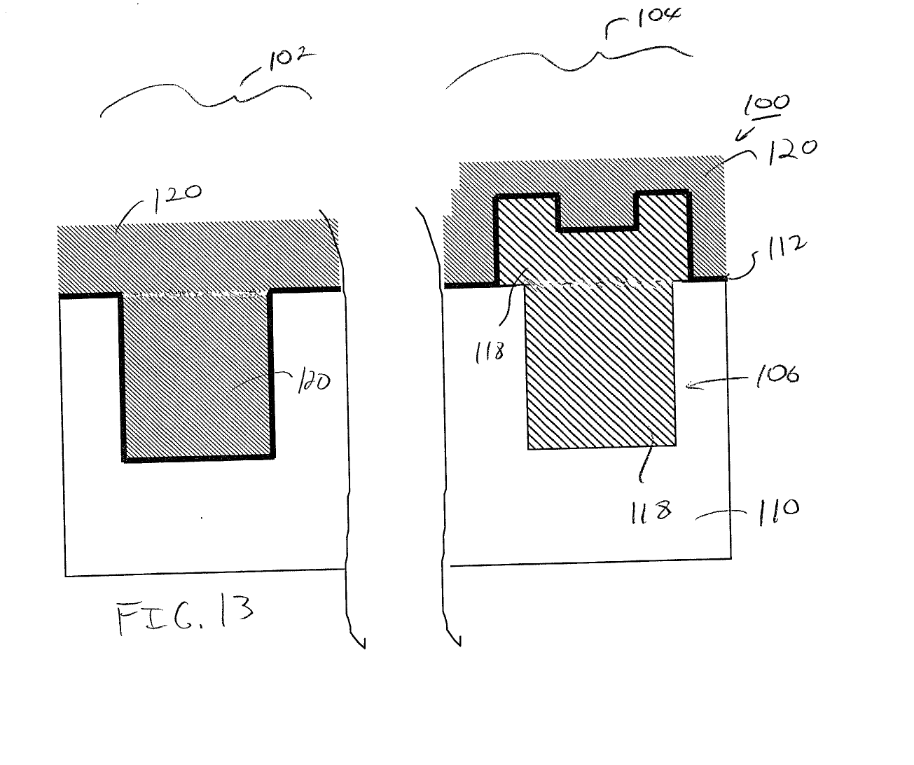

Referring to FIG. 13, metal layer 120, which may include, for example, copper, tungsten, aluminum, titanium, etc. is deposited. deposition of layer 120 may be by a chemical vapor deposition process or any other suitable deposition process.

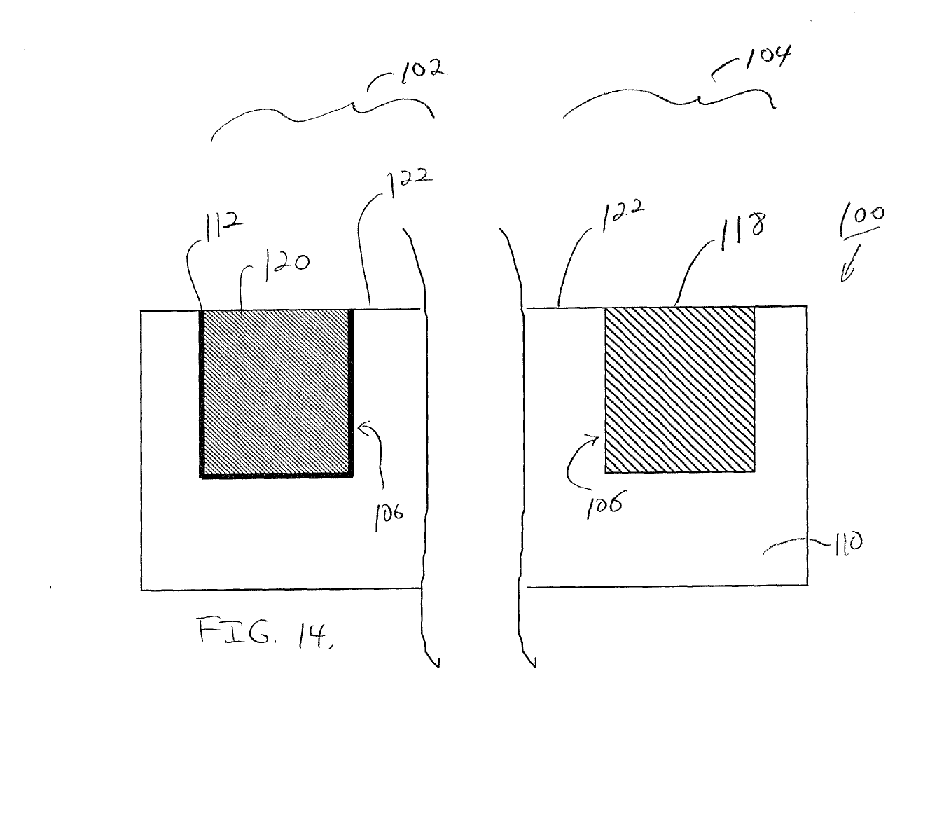

Referring to FIG. 14, metal layer 120 (and block material outside of trench 106 in region 104, if present) is planarized, preferably by a chemical-mechanical polishing (CMP) process. This removes metal layer 120 and seed layer 112, if present, from a top surface 122 in regions including regions 102 and 104.

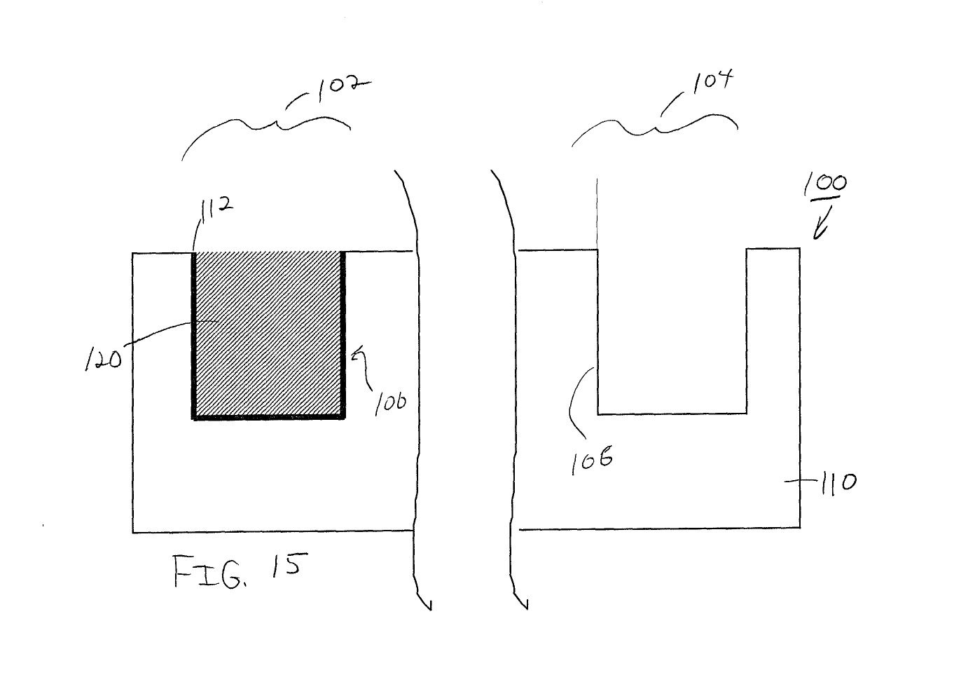

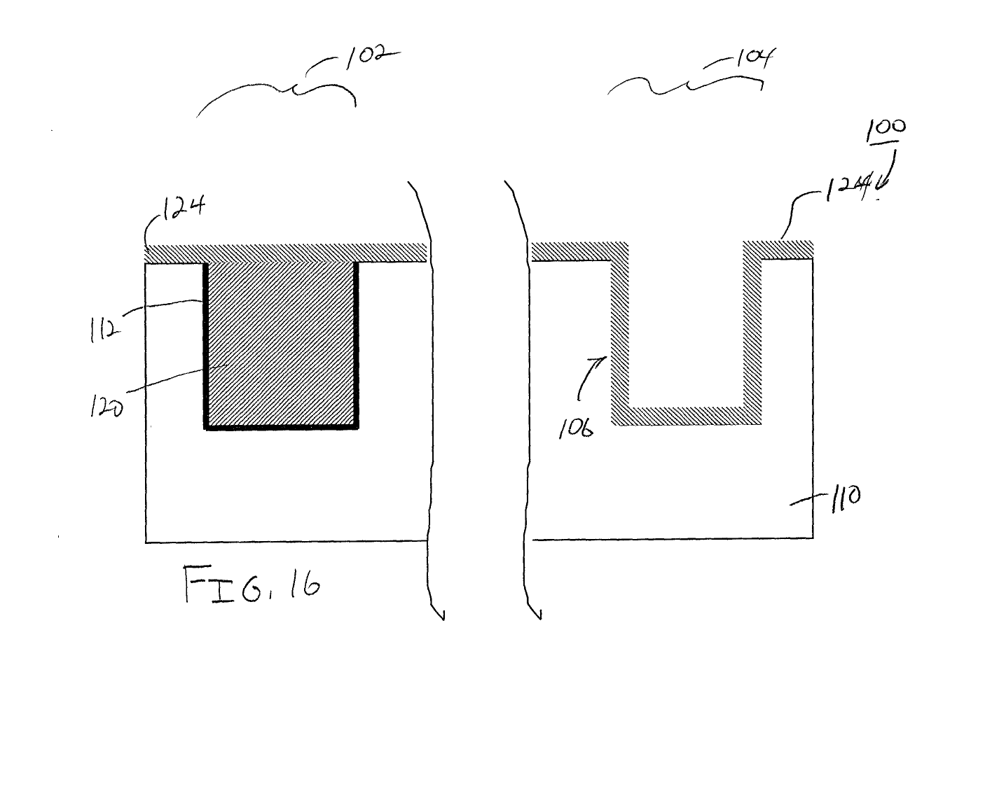

Referring to FIGS. 15 and 16, block material 118 is removed from trench 106 in alignment region 104. A blanket metal 124 (FIG. 16) may be deposited over wafer 100. The blanket metal deposition is thin enough not to fill trench 106 in region 104. Advantageously, since trench 106 in region 104 is not filled with metal, trench 106 in region 104 provides an alignment mark suitable for scattering alignment systems, such as for example, laserlight scattering alignment (LSA) systems. (See FIG. 9). Trench 106 in region 104 maintains its topographical features to provide distinct interfaces against which a photomask or subsequently processed layers can be aligned.

Blanket metal 124, which may include, for example, copper, tungsten, titanium, aluminum, etc. is patterned using a conventional lithography process in which a photomask (not shown) is aligned to alignment mark (trench 106 in region 104) to provide alignment between the underlying metal layer 120 and the pattern to be formed in blanket metal 124.

The present invention solves the problem of insufficient contrast between alignment features by preventing metal from being deposited in the etched trenches of alignment marks. By providing a blocking mask, which is formed in the trench and is opened after the metal deposition. The metal deposition is effectively blocked. The blocking material or mask may include removal of a seed layer (by a wet etch or dry etch method), as used for copper deposition, or by the deposition of an additional layer, for example silicon nitride, which prevents the metal from being deposited.

Advantageously, the blocking mask can be exposed by employing, for example, mid ultraviolet (MUV) lithography, which does not have high requirements in terms of overlay and critical dimension (CD) control. The wet etch, or dry etch of the seed layer may be performed by employing standard etch methods.

Since the present invention provides a distinct and more pronounced topography, improved alignment signal quality is provided. This means that LSA techniques may be employed after a blanket metal deposition and provide improved alignment and overlay. The present invention may be extended to different alignment mark structures as well as different semiconductor device alignments. For example, the present invention may be employed with thin film transistor technology for liquid crystal display, or another other device which requires alignment between layers or processes.

Having described preferred embodiments for high contrast lithography alignment marks for semiconductor manufacturing (which are intended to be illustrative and not limiting), it is noted that modifications and variations can be made by persons skilled in the art in light of the above teachings. It is therefore to be understood that changes may be made in the particular embodiments of the invention disclosed which are within the scope and spirit of the invention as outlined by the appended claims. Having thus described the invention with the details and particularity required by the patent laws, what is claimed and desired protected by Letters Patent is set forth in the appended claims.

What is claimed is:

1. A method for providing contrast for alignment marks after a blanket metal deposition, comprising the steps of:
providing at least one trench in a first region and at least one trench in an alignment mark region of a semiconductor wafer;
depositing a first metal on the wafer;
blocking the first metal from filling the at least one trench in the alignment mark region to maintain the at least one trench in the alignment mark region in an unfilled state;
planarizing the wafer to remove the first metal from a top surface; and
blanket depositing a second metal layer on the first region and the alignment mark region such that the at least one trench in the alignment mark region is suitable for use as a scattering alignment mark.

2. The method as recited in claim 1, wherein the step of blocking the first metal deposition includes the steps of:
forming a seed layer over the wafer;
patterning a resist layer over the seed layer such that the seed layer in the at least one trench in the alignment mark region is exposed; and
etching the seed layer from the at least one trench in the alignment mark region such that when the first metal layer leaves the at least one trench in the alignment mark region unfilled after the deposition of the first metal layer.

3. The method as recited in claim 1, further comprising the step of scanning the wafer with laserlight to determine the position of the at least one trench in the alignment mark region.

4. The method as recited in claim 3, wherein the step of scanning the wafer with laserlight includes performing a laserlight scattering alignment.

5. The method as recited in claim 1, wherein the step of blanket depositing the second metal layer includes blanket depositing the second metal layer to a thickness less than an amount needed to completely fill the at least one trench in the alignment mark region.

6. The method as recited in claim 1, wherein the step of blocking the first metal deposition includes the steps of:
forming a block layer in the first region and in the alignment mark region to fill the at least one trench; and
patterning the block layer to remove the block layer from portions of the wafer other than the at least one trench in the alignment mark region.

7. A method for providing contrast for alignment marks after a blanket metal deposition, comprising the steps of:
etching at least one trench in a first region and at least one trench in an alignment mark region of a semiconductor wafer;
forming a seed layer in the first region and the alignment mark region;
removing the seed layer from the at least one trench in the alignment mark region;
depositing a metal layer on the semiconductor wafer to fill the at least one trench in the first regions without filling the at least one trench in the alignment mark region;
planarizing the metal layer and the seed layer; and
blanket depositing a second metal layer on the first region and the alignment mark region such that the at least one trench in the alignment mark region is suitable for use as a scattering alignment mark.

8. The method as recited in claim 7, wherein the step of removing the seed layer includes the steps of:
patterning a resist layer such that the at least one trench in the alignment mark region is exposed; and
etching the seed layer from the at least one trench in the alignment mark region.

9. The method as recited in claim 7, further comprising the step of scanning the wafer with laserlight to determine the position of the at least one trench in the alignment mark region.

10. The method as recited in claim 9, wherein the step of scanning the wafer with laserlight includes performing a laserlight scattering alignment.

11. The method as recited in claim 7, wherein the step of blanket depositing the second metal layer includes blanket depositing the second metal layer to a thickness less than an amount needed to completely fill the at least one trench in the alignment mark region.

12. A method for providing contrast for alignment marks after a blanket metal deposition, comprising the steps of:
etching at least one trench in a first region and at least one trench in an alignment mark region of a semiconductor wafer;
forming a block layer in the first region and in the alignment mark region to fill the at least one trench;
patterning the block layer to remove the block layer from portions of the wafer other than the at least one trench in the alignment mark region;
depositing a metal layer on the semiconductor wafer to fill the at least one trench in the first regions, the metal layer being excluded from the at least one trench in the alignment mark region by the block layer;
planarizing the metal layer;
removing the block layer from the at least one trench in the alignment mark region; and
blanket depositing a second metal layer on the first region and the alignment mark region such that the at least one trench in the alignment mark region is suitable for use as a scattering alignment mark.

13. The method as recited in claim 12, wherein the step of depositing the metal layer includes the steps of:
forming a seed layer in the first region and the block layer in the at least one trench in the alignment mark region.

14. The method as recited in claim 12, further comprising the step of scanning the wafer with laserlight to determine the position of that the at least one trench in the alignment mark region.

15. The method as recited in claim 14, wherein the step of scanning the wafer with laserlight includes performing a laserlight scattering alignment.

16. The method as recited in claim 12, wherein the block layer includes silicon nitride.

17. The method as recited in claim 12, wherein the step of patterning the block layer includes the steps of:
forming a blocking mask by depositing a photoresist on the blocking layer;
patterning the photoresist to remain over the at least one trench in the alignment mark region; and
removing the blocking layer from portions of the wafer other than the at least one trench in the alignment mark region.

18. The method as recited in claim 17, wherein the photoresist includes a mid ultraviolet (MUV) photoresist.
